(19) United States
(12) Patent Application Publication
(10) Pub. No.: US 2008/0179629 A1
(43) Pub. Date: Jul. 31, 2008

(54) SEMICONDUCTOR DEVICE

(75) Inventor: Nobuaki YASUTAKE, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/013,162

(22) Filed: Jan. 11, 2008

(30) Foreign Application Priority Data
Jan. 11, 2007 (JP) 2007-003496

(51) Int. Cl. H01L 29/778

(52) U.S. Cl. 257/190; 257/E29.246

(57) ABSTRACT

In one aspect of the present invention, a semiconductor device may include an isolation region provided in a semiconductor substrate and defining an active region, a gate electrode provided on the semiconductor substrate via a gate dielectric layer in the active region, a channel region provided below the gate electrode, a strain supplying layer provided between the channel region and the isolation region and being epitaxially grown, and configured to generate a strain in the channel region, a silicide layer provided on the strain supplying layer, a reformed layer provided between the silicide layer and the semiconductor substrate near the isolation region, and provided under the strain supplying layer, a source/drain region provided in a part of the strain supplying layer and a part of the reformed layer.

### CROSS REFERENCE TO RELATED APPLICATION

This application is based upon and claims the benefit of priority from Japanese Patent Application No. 2007-3496, filed on Jan. 11, 2007, the entire contents of which are incorporated herein by reference.

### BACKGROUND

In a conventional semiconductor device, a recess is formed in the Si substrate and a SiGe crystal which has a different lattice constant to the Si substrate is epitaxially grown on the recess so as to induce a strain to the channel.

However, a gap may be provided between the isolation region (STI) and the grown SiGe layer, since the SiGe crystal is grown toward a predetermined direction and the SiGe crystal is not grown from the isolation region.

So when the SiGe layer which has a gap near the isolation region is silicided, a silicide may be formed even in a deeper portion along the gap. When the silicide is in contact with the Si substrate, the silicidation reaction is proceeded radically toward inside of the Si substrate, since the ternary compound NiSiGe or the like is thermal dynamically unstable. So the silicide layer may be also provided in the Si substrate below the source/drain region. In such case, the junction current from the silicide to the Si substrate may me increased.

### SUMMARY

Aspects of the invention relate to an improved semiconductor device.

In one aspect of the present invention, a semiconductor device may include a semiconductor substrate, an isolation region provided in the semiconductor substrate and defining an active region, a gate electrode provided on the semiconductor substrate via a gate dielectric layer in the active region, a channel region provided below the gate electrode, a strain supplying layer provided between the channel region and the isolation region and being epitaxially grown, and configured to generate a strain in the channel region, a silicide layer provided on the strain supplying layer, a reformed layer provided between the silicide layer and the semiconductor substrate near the isolation region, and provided under the strain supplying layer, a source/drain region provided in a part of the strain supplying layer and a part of the reformed layer.

In one aspect of the present invention, a semiconductor device may include a semiconductor substrate, an isolation region provided in the semiconductor substrate and defining an active region, a gate electrode provided on the semiconductor substrate via a gate dielectric layer in the active region, a channel region provided below the gate electrode, a strain inducing layer provided between the channel region and the isolation region and being epitaxially grown, and configured to generate a strain in the channel region, and having a slanted surface which is in contact with the isolation region, a silicide layer provided on the strain inducing layer, an interposed layer provided between the silicide layer and the semiconductor substrate near the isolation region, and provided under the strain inducing layer, and having an element in the semiconductor substrate, a source/drain region provided in a part of the strain inducing layer and a part of the interposed layer.

### BRIEF DESCRIPTIONS OF THE DRAWINGS

A more complete appreciation of the invention and many of the attendant advantages thereof will be readily obtained as the same becomes better understood by reference to the following detailed description when considered in connection with the accompanying drawings.

FIG. 1 is a cross sectional view of a semiconductor device in accordance with a first embodiment.

FIGS. 2A-2M are cross sectional views showing a manufacturing process of the semiconductor device in accordance with a first embodiment.

FIG. 3 a cross sectional view of a semiconductor device in accordance with the second embodiment.

FIG. 4 a cross sectional view of a semiconductor device in accordance with a third embodiment.

FIGS. 5A-5F are cross sectional views showing a manufacturing process of the semiconductor device in accordance with the third embodiment.

### DETAILED DESCRIPTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as next described, wherein like reference numerals designate identical or corresponding parts throughout the several views.

### First Embodiment

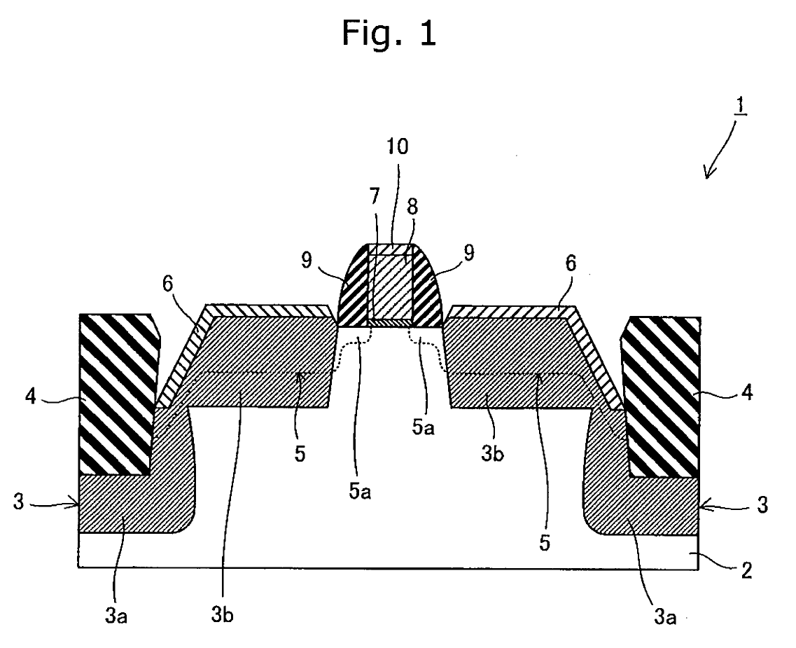

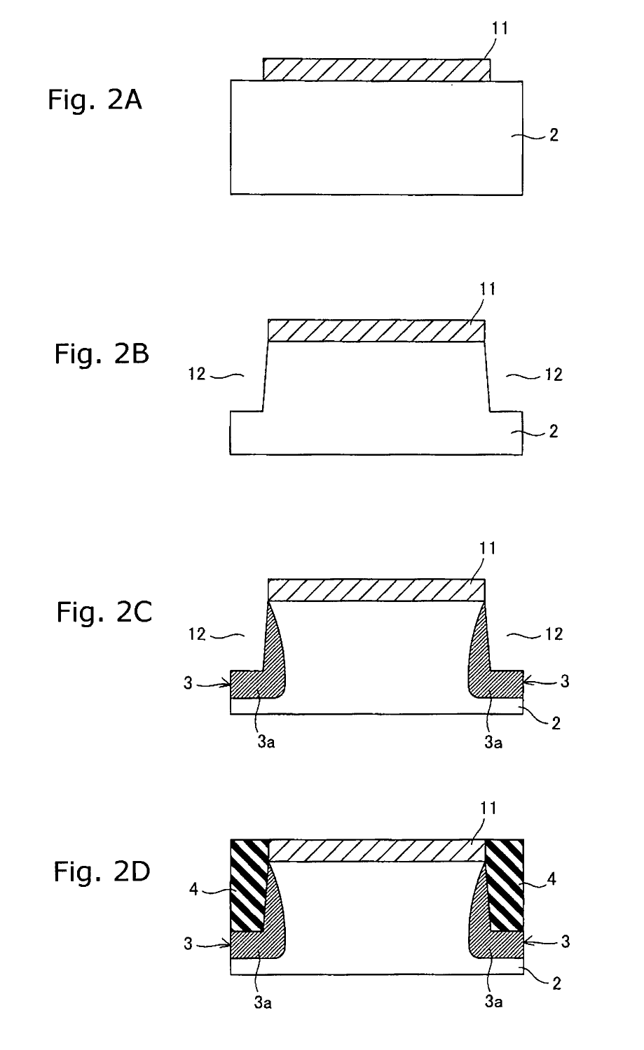

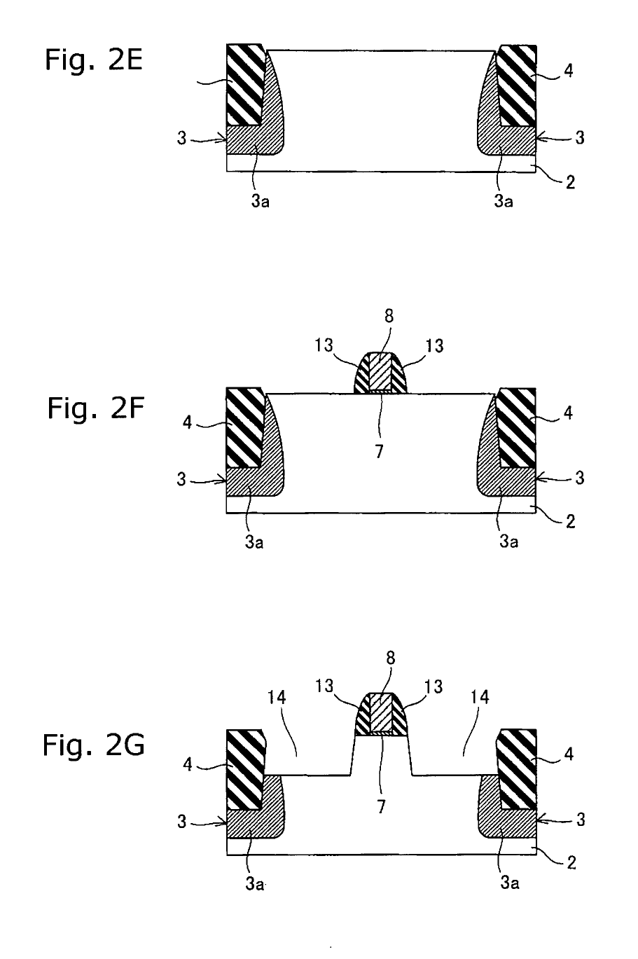

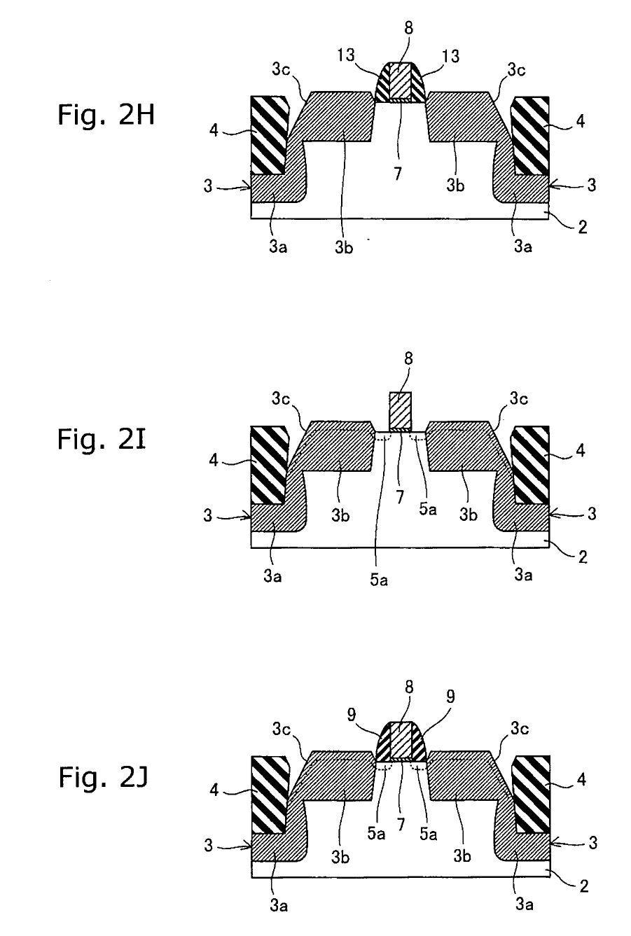

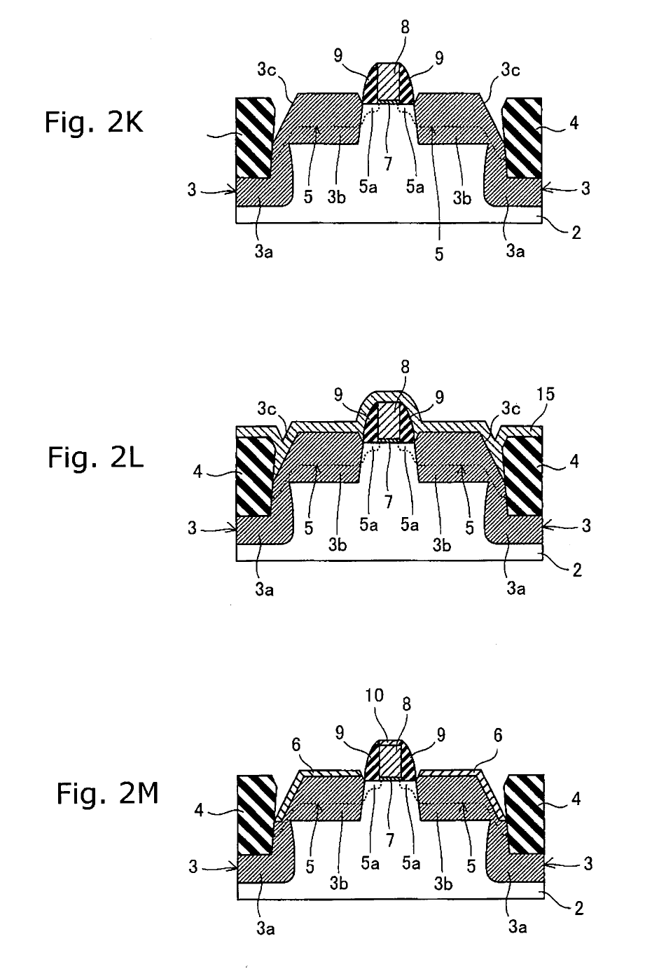

A first embodiment of the present invention will be explained hereinafter with reference to FIGS. 1-2D.

FIG. 1 is a cross sectional view of a semiconductor device 1 in accordance with the first embodiment. In the semiconductor device 1, a transistor provided in an active region defined by an isolation region 4.

The transistor is a p type transistor, which has a gate electrode 8 provided on a Si substrate 2 via a gate dielectric layer 7, a gate sidewall 9, a SiGe layer 3, a source/drain region 5 provided in the Si substrate 2 and the SiGe layer 3, a gate silicide layer 10 provided on the gate electrode 8, and a source/drain silicide layer 6 provided on the source/drain region 5. The source/drain region 5 includes an extension region 5a.

The isolation region 4 is made of, for example, a dielectric such as a SiO₂ or the like and has a STI (Shallow Trench Isolation) structure.

The gate electrode 8 is made of, for example, polycrystalline silicon. The gate silicide layer 10 is made of, for example, a silicide having a metal such as a Ni, Pt, Co, Er, NiPt, CoNi or the like.

The gate dielectric layer 7 is made of, for example, a SiO₂, SiN, or high dielectric constant material (high-k material; Hf based material such as HfSiON, HfSiO and HfO; Zr based material such as ZrSiON, ZrSiO, ZrO; Y based material Y₂O₃).

The gate sidewall 9 is made of, for example, a single layered SiN, a two layered structure having SiN and SiO₂ or a three layered structure. An offset spacer may be provided between the gate electrode 8 and the gate sidewall 9.

The source/drain region 5 and the extension region 5a is formed by, for example, implanting a p type impurity ion such as B, BF2 or the like into the Si substrate 2 and SiGe layer 3.

The ion implantation region 3a of the SiGe layer 3 is formed by implanting a Ge ion into the Si substrate 2. The SiGe layer 3 has an ion implantation region 3a which is abutting to the isolation region 4 and an epitaxial growth region 3b which is formed by an epitaxially growth. It may be preferable that the Ge concentration in the ion implantation region 3a and the epitaxial growth region 3b is 10-30 atom %. When the Ge concentration is less than 10 atom %, the stress to the channel may be small. When the Ge concentration is more than 30 atom %, the crystal defect in the SiGe layer 3 may be large.

The SiGe crystal has a different lattice constant to the Si crystal. So, a strain is induced from the SiGe layer 3 to the channel region in the Si substrate 2. Especially, the epitaxial growth region 3b improves the electron mobility in the channel region by providing a compressive stress to the channel region. The depth of the epitaxial growth region 3b is preferably no more than 100 nm. Even if the depth of the epitaxial growth region 3b is more than 100 nm, the strain generated in the channel region is not increased as much and manufacturing time and throughput may be worsened.

A slanted portion is provided in the epitaxial growth region 3b near the isolation region 4. A gap is provided the isolation region 4 and the source/drain silicide layer 6 on the epitaxial growth region 3b.

The source/drain silicide layer 6 is made of, for example, a compound of SiGe and a metal such as a Ni, Pt, Co, Er, NiPt or the like.

The source/drain silicide layer 6 is provided on the SiGe layer 3 and not in contact with the Si substrate 2. In other words, the SiGe layer 3 is interposed between the source/drain silicide layer 6 and the Si substrate 2.

The lower part of the source/drain silicide layer 6 is provided above the bottom of bottom part of the source/drain region 5.

Next, a manufacturing process of the semiconductor device 1 will be explained hereinafter with reference to FIGS. 2A-2M.

As shown in FIG. 2A, a resist 11 is provided on the Si substrate 2.

As shown in FIG. 2B, a first trench 12 is provided by etching with the resist 11 as a mask.

As shown in FIG. 2C, the Ge is implanted into the Si substrate 2 from the surface of the first trench 12 by ion implantation method. So the ion implantation region 3a of the SiGe layer 3 is provided near the surface of the first trench 12.

As shown in FIG. 2D, a dielectric material is provided so as to fill the first trench 12 and a planarization is provided such that the resist 11 is exposed.

As sown in FIG. 2E, the resist 11 is removed by etching.

As shown in FIG. 2F, the gate dielectric layer 7, the gate electrode 8 and a dummy sidewall 13 is provided on the Si substrate 2.

As shown in FIG. 2G, a second trench 14 is provided in the Si substrate 2 by etching with the dummy sidewall 13 as a mask edge. The second trench 14 is provided with self-aligned to the isolation region 4 and the gate electrode 8.

As shown in FIG. 2H, the SiGe crystal is epitaxially grown on the exposed surface of the Si substrate 2 and the SiGe layer 3. So the epitaxial growth region 3b is provided. The epitaxial growth is provided in the chemical deposition chamber, and an ambient with monosilane (SiH₄) or dichlorosilane (SiHCl₂), germanium tetrahydride (GeH₄), hydrogen gas and the like in 700-750 Centigrade.

The SiGe crystal is grown toward in a predetermined direction by the crystal characteristic. The SiGe crystal is not grown from the isolation region 4. So a facet 3c is provided on a top surface of the SiGe layer 3. The facet 3c is slanted from the main surface of the Si substrate 2. And the gap is provided between the isolation region 4 and the facet 3c of the SiGe layer 3.

As shown in FIG. 2I, after the dummy sidewall 13 is removed, an impurity such as boron (B) or the like is implanted into the Si substrate 2 and the SiGe layer 3, and the extension region 5a of the source/drain region 5 is formed.

As shown in FIG. 2J, the gate sidewall 9 is formed on a side of the gate electrode 8.

As shown in FIG. 2K, the impurity such as boron (B) or the like is implanted into the Si substrate 2 and the SiGe layer 3 to the deeper portion than the extension region 5a, and the source/drain region 5 is formed. The source/drain region 5 near the isolation region 4 is formed in a deeper portion along the facet 3c of the SiGe layer 3

As shown in FIG. 2L, a metal layer 15 which is made of a Ni or the like is provided on the surface of the gate electrode 8 and the SiGe layer 3 by sputtering.

As shown in FIG. 2M, a heat treatment is provided, the metal layer 15 and the gate electrode 8 are reacted, and the metal layer 15 and the SiGe layer 3 are reacted. So the gate electrode 8 and the SiGe layer 3 are silicided. Thus the gate silicide layer 10 and the source/drain silicide layer 6 are formed on the gate electrode 8 and the SiGe layer 3, respectively.

In case the ion implantation region 3a of the SiGe layer 3 is not provided, the source/drain silicide layer 6 may be in contact with the Si substrate 2. When there is a portion where the silicide layer 6 and the Si substrate 2 are in touch, the silicidation reaction proceeds to the inside of the Si substrate 2. In such case, a junction leak current from the source/drain silicide layer 6 to the Si substrate 2 is increased.

In case the source/drain silicide layer 6 is a Ni silicide, the Ni in the source/drain silicide layer 6 is agglomerated toward the Si in the Si substrate 2 so as to form stable NiSi and the silicidation reaction proceeds to the Si substrate2, since the ternary compound NiSiGe is thermal-dynamically unstable. The degration of the surface morphology in the source/drain silicide layer 6 may occur with the agglomeration of Ni, and the variation of the resistivity in the source/drain silicide layer 6 may be increased.

On the other hand, in the semiconductor device 1 of the first embodiment, the source/drain silicide layer 6 is not in contact with the Si substrate 2, since a reformed layer of the Si substrate 2 (interposed layer) which is the ion implantation region 3a is provided under the epitaxial growth region 3b of the SiGe layer 3. So the silicidation reaction does not proceed to the Si substrate 2. Namely, the ion implantation region 3a may function as the interposed layer between the source/drain silicide layer 6 and the Si substrate 2.

According to the semiconductor device in the first embodiment, the junction leak current from the source/drain silicide layer 6 to the Si substrate 2 and the variation of the resistivity may be reduced, since the source/drain silicide layer 6 is not in contact with the Si substrate 2.

### Second Embodiment

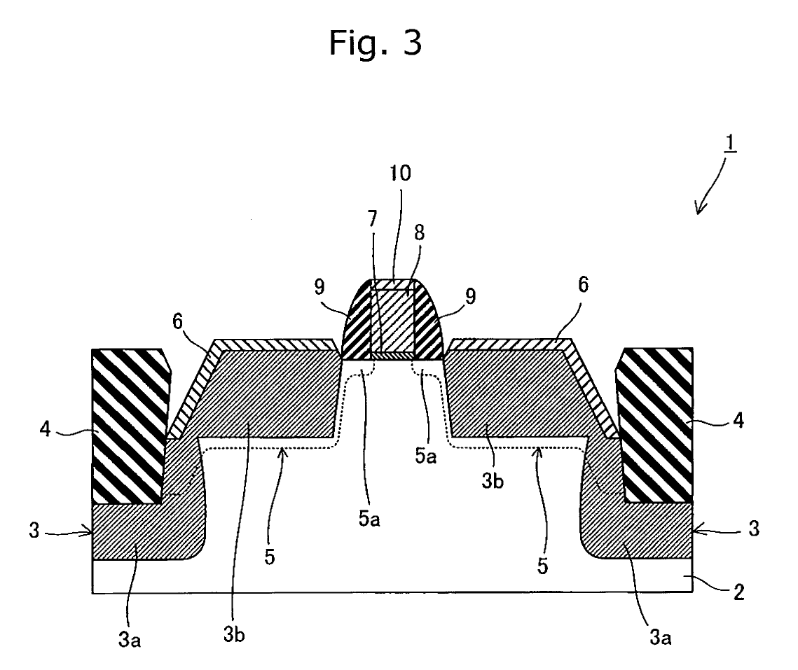

A second embodiment is explained with reference to FIG. 3.

In the second embodiment, the position (depth) of the source/drain region 5 is different from that in the first embodiment.

FIG. 3 a cross sectional view of a semiconductor device in accordance with the second embodiment.

The bottom part of the source/drain region 5 is deeper than the bottom part of the epitaxial growth region 3b of the SiGe layer 3 and is provided in the Si substrate 2 under the epitaxial growth region 3b.

The source/drain silicide layer 6 is provided on the SiGe layer 3 and is not in contact with the Si substrate 2. The source/drain silicide layer 6 is not provided in a deeper portion than the source/drain region 5. Namely, the lower part of the source/drain silicide layer 6 is provided above the bottom of bottom part of the source/drain region 5.

The semiconductor device 1 as shown in FIG. 3 is manufactured such that the impurity for source/drain region 5 is implanted to deeper portion the bottom surface of epitaxial growth region 5b of the SiGe layer 3 during the process shown in FIG. 2K.

When the source/drain silicide layer 6 is provided in a deeper portion than the source/drain region 5, the leak current may occur from the source/drain silicide layer 6 to the Si substrate 2 even if the source/drain silicide layer 6 is not in contact with the Si substrate 2. So the source/drain region 5 is provided enough deep to interpose between the source/drain silicide layer 6 and the Si substrata 2.

### Third Embodiment

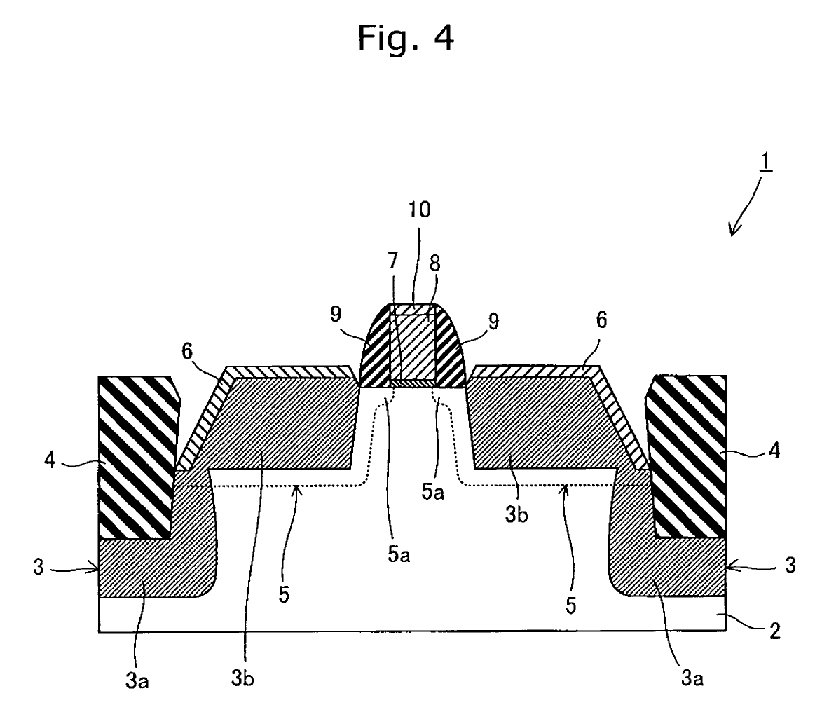

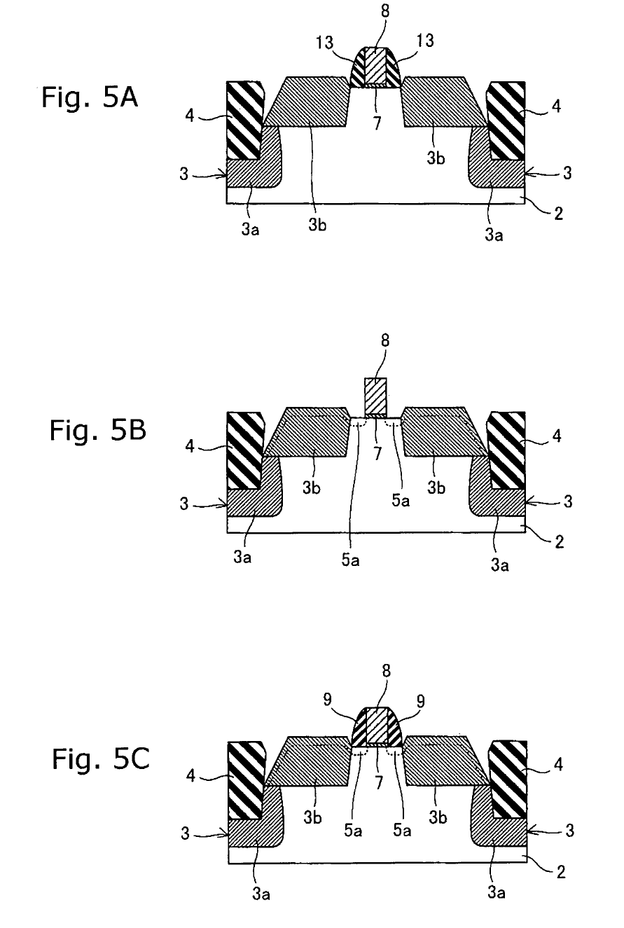

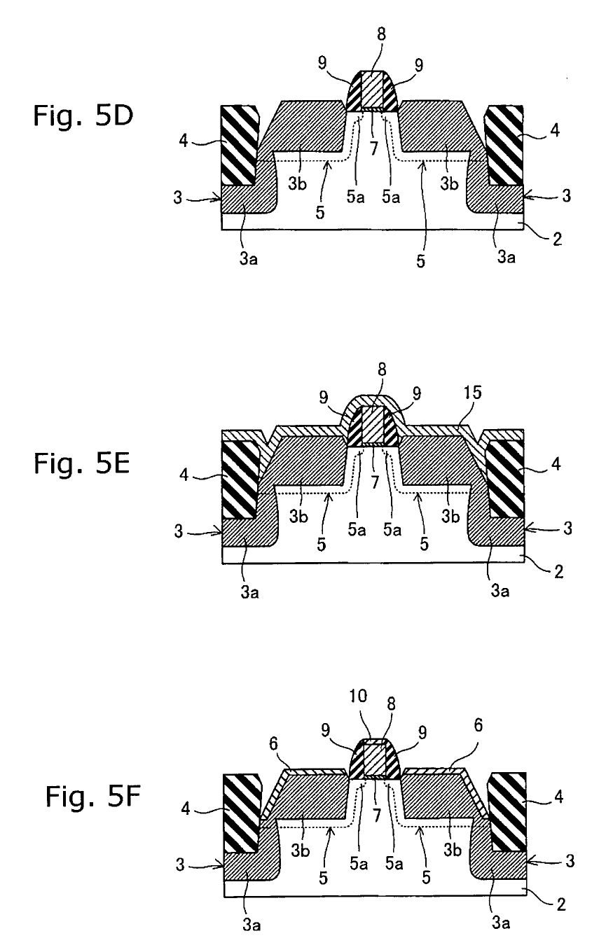

A third embodiment is explained with reference to FIGS. 4-5B.

In this third embodiment, the source/drain region 5 is different in shape and formation process from the source/drain region 5 in the first and second embodiment.

FIG. 4 a cross sectional view of a semiconductor device in accordance with a third embodiment.

The bottom of the source/drain region 5 is provided deeper than the epitaxial growth region 3b of the SiGe layer 3 and is provided in the Si substrate 2 under the epitaxial growth region 3b.

Near the isolation region 4, the shape of the source/drain region 5 is not corresponding to the top surface (facet 3c) of the SiGe layer 3 with comparing to that in the first embodiment. The bottom of the source/drain region 5 near the isolation region 4 is substantially horizontal.

The source/drain region 5 is formed by diffusing and activating a p type impurity ion (B, BF₂ or the like) in the epitaxial growth region 3b of the SiGe layer 3 with a heat treatment.

The source/drain silicide layer 6 is formed on the SiGe layer 3 and not in contact with the Si substrate 2. The source/drain silicide layer 6 is not provided in a deeper portion than the source/drain region 5.

Next, a manufacturing process of the semiconductor device 1 in accordance with the third embodiment will be explained hereinafter with reference to FIGS. 5A-5F.

FIGS. 5A-5F are cross sectional views showing a manufacturing process of the semiconductor device in accordance with the third embodiment.

A process as shown FIGS. 2A-2G is provided, and the second trench 14 is provided in the Si substrate2.

As shown in FIG. 5A, the SiGe crystal including a p type impurity ion such as B or the like is epitaxially grown on the exposed surface of the Si substrate 2 and the SiGe layer 3. So the epitaxial growth region 3b is provided. The epitaxial growth is provided in the chemical deposition chamber, and an ambient with monosilane (SiH₄) or dichlorosilane (SiHCl₂), germanium tetrahydride (GeH₄), hydrogen gas and the like in 700-750 Centigrade.

The SiGe crystal is grown toward in a predetermined direction by the crystal characteristic. The SiGe crystal is not grown from the isolation region 4. So a facet 3c is provided on a top surface of the SiGe layer 3. The facet 3c is slanted from the main surface of the Si substrate 2. And the gap is provided between the isolation region 4 and the facet 3c of the SiGe layer 3.

As shown in FIG. 5B, after the dummy sidewall 13 is removed, an impurity such as boron (B) or the like is implanted into the Si substrate 2 and the SiGe layer 3, and the extension region 5a of the source/drain region 5 is formed.

As shown in FIG. 5C, the gate sidewall 9 is formed on a side of the gate electrode 8.

As shown in FIG. 5D, the p type impurity ion in the SiGe layer 3 is diffused to the Si substrate 2 by a heat treatment, and the source/drain region 5 is provided. For example, the bottom of the source/drain region 5 may be provided no more than 10 nm from the bottom of the SiGe layer 3 by the heat treatment in about 900-1100 Centigrade ambient. The shape of the source/drain region 5 is not corresponding to the facet 3c of the SiGe layer 3.

As shown in FIG. 5E, a metal layer 15 which is made of a Ni or the like is provided on the surface of the gate electrode 8 and the SiGe layer 3 by sputtering.

As shown in FIG. 5F, a heat treatment is provided, the metal layer 15 and the gate electrode 8 are reacted, and the metal layer 15 and the SiGe layer 3 are reacted. So the gate electrode 8 and the SiGe layer 3 are silicided. Thus the gate silicide layer 10 and the source/drain silicide layer 6 are formed on the gate electrode 8 and the SiGe layer 3, respectively.

Embodiments of the invention have been described with reference to the examples. However, the invention is not limited thereto.

For example, a SiC layer or other layer having Si may be provided the substitute of the SiGe layer 3. The SiC layer may be used in n type transistor, since the SiC layer provides a tensile stress to the channel so as to improve mobility of electron. The n type impurities for the source/drain region 5 are As, P or the like in the n type transistor.

A raised source/drain structure, in which the top surface of the source/drain region is provided higher than the bottom of the gate dielectric layer 7, is applied in the semiconductor device 1.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A semiconductor device, comprising:
a semiconductor substrate;
an isolation region provided in the semiconductor substrate and defining an active region;
a gate electrode provided on the semiconductor substrate via a gate dielectric layer in the active region;
a channel region provided below the gate electrode in the semiconductor substrate;
a strain inducing layer provided between the channel region and the isolation region, and configured to induce a strain in the channel region;
a silicide layer provided on the strain inducing layer;
a reformed layer provided between the silicide layer and the semiconductor substrate near the isolation region, and provided under the strain inducing layer;
a source/drain region provided in a part of the strain inducing layer and a part of the reformed layer and under the silicide layer.

2. A semiconductor device of claim 1, wherein a part of the reformed layer is provided under the isolation region.

3. A semiconductor device of claim 1, wherein the strain inducing layer includes at least one of SiGe and SiC.

4. A semiconductor device of claim 3, wherein the reformed layer includes at least one of SiGe and SiC.

5. A semiconductor device of claim 1, wherein the reformed layer is in contact with the isolation region.

6. A semiconductor device of claim 1, wherein the silicide layer is not in contact with the semiconductor substrate.

7. A semiconductor device of claim 1, wherein the semiconductor substrate is a Si substrate, the strain inducing layer and the reformed layer are one of SiGe and Sic.

8. A semiconductor device of claim 1, wherein the reformed layer is formed by implanting ion into the semiconductor substrate.

9. A semiconductor device, comprising:
a semiconductor substrate;
an isolation region provided in the semiconductor substrate and defining an active region;
a gate electrode provided on the semiconductor substrate via a gate dielectric layer in the active region;
a channel region provided below the gate electrode in the semiconductor substrate;
a strain inducing layer provided between the channel region and the isolation region, and configured to generate a strain in the channel region, and having a slanted surface which is slanted from a top surface of the semiconductor substrate and is in contact with the isolation region;
a silicide layer provided on the strain inducing layer;
an interposed layer provided between the silicide layer and the semiconductor substrate near the isolation region, and provided under the strain inducing layer, and having an element in the semiconductor substrate;
a source/drain region provided in a part of the strain inducing layer and a part of the interposed layer and under the silicide layer.

10. A semiconductor device of claim 9, wherein the silicide layer is provided on the slanted surface of the strain inducing layer.

11. A semiconductor device of claim 9, wherein the strain inducing layer includes at least one of SiGe and SiC.

12. A semiconductor device of claim 9, wherein the slanted surface is a facet of the strain inducing layer.

13. A semiconductor device of claim 9, wherein a part of the interposed layer is provided under the isolation region.

14. A semiconductor device of claim 9, wherein a bottom edge of the source/drain region is provided deeper than a boundary between the strain inducing layer and the semiconductor substrate.

15. A semiconductor device of claim 9, wherein the interposed layer is provided below the slanted surface of the strain inducing layer.

16. A semiconductor device of claim 9, wherein the interposed layer is made of a same material as the strain inducing layer.

17. A semiconductor device of claim 9, wherein the silicide layer is not in contact with the semiconductor substrate.

18. A semiconductor device of claim 9, wherein the interposed layer is formed by implanting ion into the semiconductor substrate.
